(19) United States
(12) Patent Application Publication
(10) Pub. No.: US 2014/0190857 A1
(43) Pub. Date: Jul. 10, 2014

(54) LIMIT MEMBER HAVING PROTECTION COVER

(71) Applicant: GUDENG PRECISION INDUSTRIAL CO., LTD., New Taipei City (TW)

(72) Inventors: JAIN-PING SHENG, NEW TAIPEI CITY (TW); TZU-JENG HSU, TAIPEI CITY (TW); CHEN-HAO CHANG, TAIPEI CITY (TW); CHENG-EN CHUNG, NEW TAIPEI CITY (TW)

(73) Assignee: GUDENG PRECISION INDUSTRIAL CO., LTD., NEW TAIPEI CITY (TW)

(21) Appl. No.: 13/774,176

(22) Filed: Feb. 22, 2013

(30) Foreign Application Priority Data
Jan. 10, 2013 (TW) 102200583

(51) Int. Cl. H01L 21/673

(52) U.S. Cl. CPC H01L 21/67369
USPC 206/454

(57) ABSTRACT

The present invention provides a limit member having a protection cover. The limit member is disposed in a substrate container and holds against the edge of at least one substrate received in the substrate container. The limit member has at least one limit portion and at least one protection cover. The protection cover is disposed on the limit portion. When the limit portion holds against the edge of the substrate, the substrate is against the protection cover on the limit portion, not being direct contact with the limit portion. This prevents the substrate from rubbing against the limit member to bring contamination particles, and further prevents the passivation layer of the substrate from being broken to pieces by the limit member to bring more contamination particles.

### BACKGROUND OF THE INVENTION

1. Field of the Invention

The present invention relates to a limit member, and more particularly to a limit member having a protection cover for a substrate container.

2. Description of the Prior Art

A semiconductor wafer must be treated with various procedures and cooperate with equipment to be transported to different workstations. A substrate container is used for transportation of wafers, preventing the wafers from being contaminated. The substrate container has a box and a door. The box has a plurality of horizontal grooves to receive a plurality of substrates. One side of the box has an opening for the user to put the wafers in the box or to take out the wafers. The door has an outer surface and an inner surface. The inner surface of the door is coupled to the opening of the box to protect the plurality of substrates in the box. Besides, the outer surface of the door is provided with a latch to open or close the box.

In the aforesaid substrate container, the semiconductor wafers are horizontally placed in the box. Therefore, during transportation of the substrate container, it is necessary to use a limit member to prevent the wafers from displacement because of vibration or moving toward the opening of the box. A conventional limit member is disposed on the inner surface of the door. The limit member has symmetrical left and right resilient arms to hold against the substrates so as to prevent the wafers from displacement because of vibration or moving toward the opening of the box during transportation of the substrate container.

However, when the conventional limit member holds against the edge of the substrate, the substrate will rub against the limit member to bring contamination particles in the substrate container. The conventional limit member is made of high strength plastic. The passivation layer of the substrate cannot bear the limit member made of high strength plastic, so it may be broken to pieces by the limit member to bring more contamination particles in the substrate container. Accordingly, the inventor of the present invention has devoted himself based on his many years of practical experiences to solve these problems.

### SUMMARY OF THE INVENTION

The primary object of the present invention is to provide a limit member having a protection cover. The limit member is disposed in a substrate container. The limit member is provided with the protection cover to hold against the edge of at least one substrate (such as, wafer, photomask, or other semiconductor substrate) received in the substrate container to prevent the limit member from getting contact with the substrate directly, and then to prevent the passivation layer of the substrate from being broken to pieces to bring more contamination particles.

According to a first aspect of the present invention, the limit member comprises a main body and at least one protection cover. The main body is disposed in a substrate container and has at least one limit portion. The protection cover is disposed on the limit portion. The protection cover holds against the edge of at least one substrate received in the substrate container.

According to a second aspect of the present invention, the limit member comprises a main body, a plurality of resilient arms, and a plurality of protection covers. The main body is mounted to a door of a substrate container. Each resilient arm has a connection end and an extension end. The connection ends of the resilient arms are connected to two sides of the main body. The extension ends of the resilient arms extend away from the main body. The extension end has a limit portion. Each protection cover is disposed on the limit portion of the extension end. Each protection cover holds against the edge of at least one substrate received in the substrate container.

According to a third aspect of the present invention, the limit member comprises at least one main body and at least one protection cover. The main body is disposed on a side wall of a box of a substrate container and has at least one limit portion. The main body is perpendicular to at least one substrate received in the substrate container. The protection cover is disposed on the limit portion. The protection cover holds against an edge of the substrate.

### BRIEF DESCRIPTION OF THE DRAWINGS

FIG. 1 is a schematic view showing the substrate container according to a first embodiment of the present invention;

FIG. 2 is a perspective view showing the limit member according to the first embodiment of the present invention;

FIG. 3 is an exploded view showing the limit member according to the first embodiment of the present invention;

FIG. 4 is a schematic view showing the limit portion and the protection cover according to the first embodiment of the present invention;

FIG. 5 is a schematic view showing the limit portion and the protection cover according to a second embodiment of the present invention;

FIG. 6 is a schematic view showing the limit portion and the protection cover according to a third embodiment of the present invention;

FIG. 7 is a schematic view showing the limit portion and the protection cover according to a fourth embodiment of the present invention; and

FIG. 8 is a partial schematic view showing the substrate container according to the first embodiment of the present invention.

### DETAILED DESCRIPTION OF THE PREFERRED EMBODIMENTS

Embodiments of the present invention will now be described, by way of example only, with reference to the accompanying drawings.

A conventional substrate container comprises a limit member therein. The limit member directly holds against the edge of at least one substrate (such as, wafer, photomask, or other semiconductor substrate) in the substrate container. The limit member is made of high strength plastic (such as, PEEK) to decrease contamination particles caused by constant rub of the edge of the substrate and the limit member. The passivation layer of the substrate is unable to bear the limit member made of high strength plastic, so the substrate may be broken to pieces by the limit member to bring more contamination particles in the substrate container. In view of the aforesaid question, the present invention provides a limit member with a protection cover to prevent the substrate from getting contact with the limit member made of high strength plastic, and then to prevent the passivation layer of the substrate from being broken to pieces by the limit member to bring more contamination particles in the substrate container.

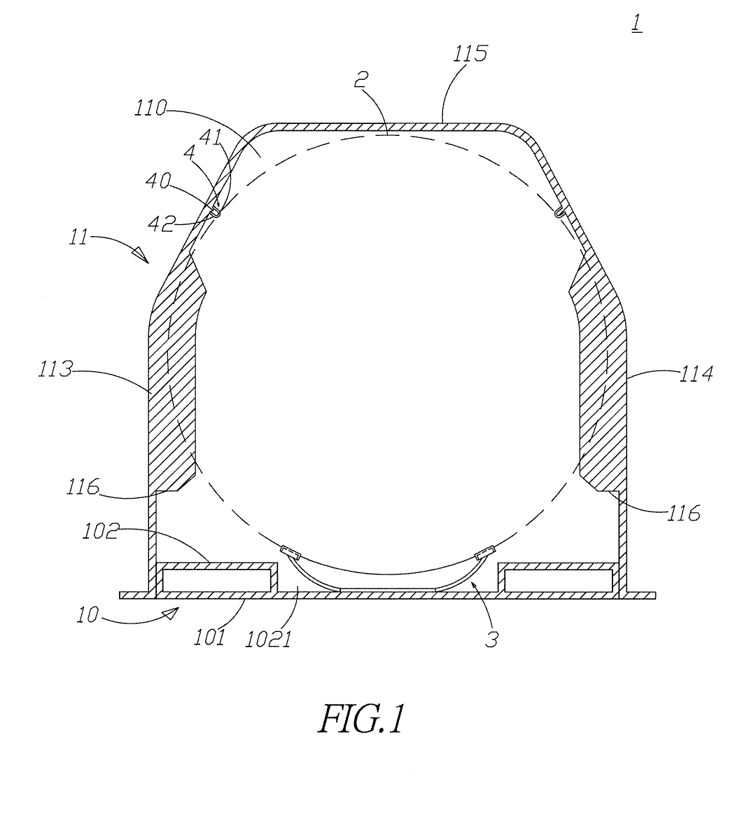

FIG. 1 is a schematic view showing the substrate container according to a first embodiment of the present invention. As shown in the drawing, this embodiment provides a substrate container 1. The substrate container 1 comprises a door 10 and a box 11. The box 11 has an accommodation space 110. The accommodation space 110 is to accommodate at least one substrate 2. The substrate 2 is a wafer, photomask, or other semiconductor substrate. The door 10 has a first surface 101 and a second surface 102 opposite the first surface 101. The second surface 102 faces the accommodation space 110 of the box 11. The second surface 102 of the door 10 has a recessed area 1021. The recessed area 1021 is adapted to receive the limit member 3. When the door 10 is coupled to the box 11, the limit member 3 of the door 10 is to hold against the edge of the substrate 2 of the box 11, preventing the substrate 2 from displacing in the box 11.

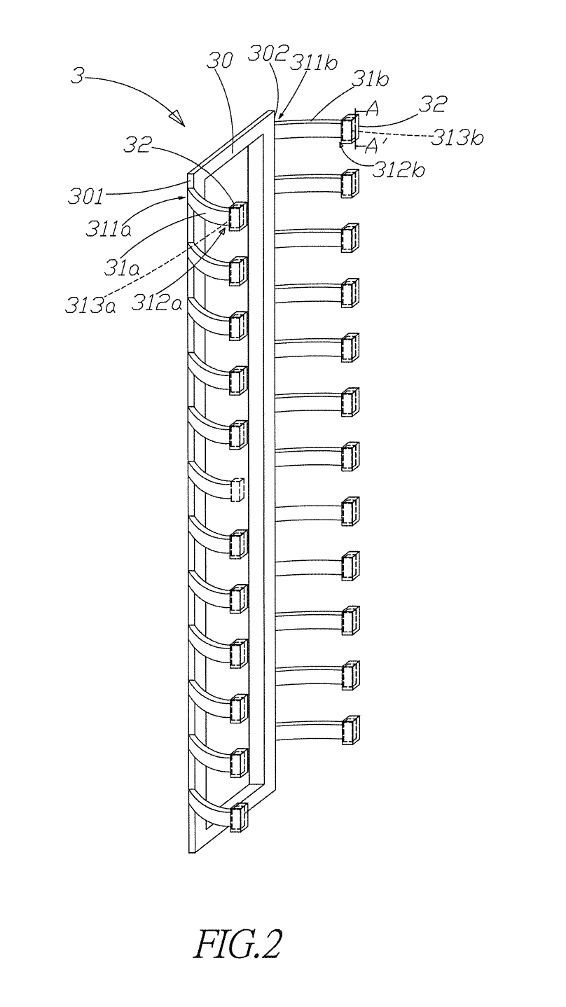

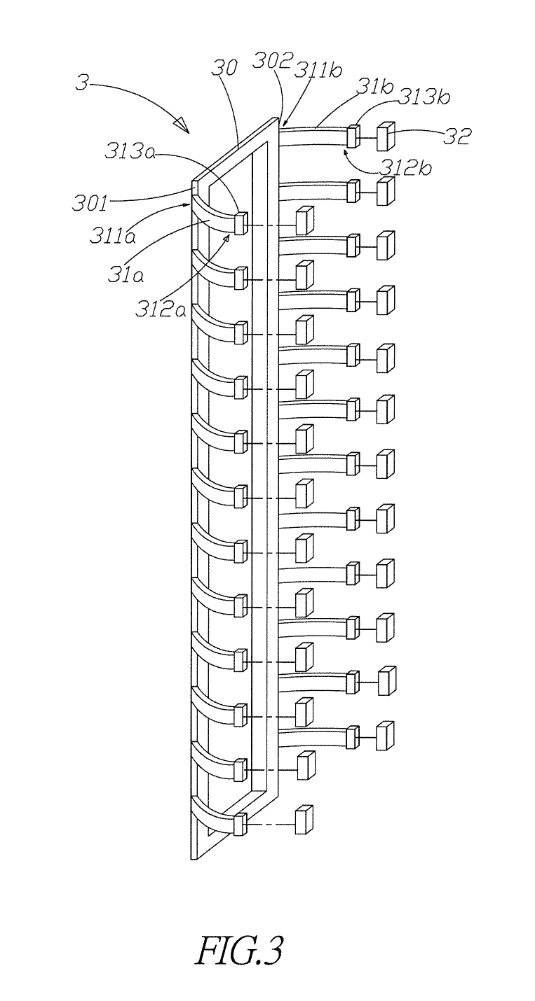

FIG. 2 is a perspective view showing the limit member according to the first embodiment of the present invention. FIG. 3 is an exploded view showing the limit member according to the first embodiment of the present invention. As shown in the drawings, the limit member 3 of this embodiment comprises a main body 30, a plurality of first resilient arms 31a, and a plurality of second resilient arms 31b. The main body 30 has a first side 301 and a second side 302 opposite the first side 301. The plurality of first resilient arms 31a is disposed at the first side 301 of the main body 30. The plurality of second resilient arms 31b is disposed at the second side 302 of the main body 30. The plurality of first resilient arms 31a and the plurality of second resilient arms 31b are spaced and arranged in order at the first side 301 and the second side 302, respectively, and symmetrically disposed relative to the main body 30. Each first resilient arm 31a has a first connection end 311a and a first extension end 312a. The first connection end 311a is connected to the first side 301 of the main body 30. The first extension end 312a extends away from the main body 30. Similarly, each second resilient arm 31b has a second connection end 311b and a second extension end 312b. The second connection end 311b is connected to the second side 302 of the main body 30. The second extension end 312b extends away from the main body 30. The extension direction of the second extension end 312b is opposite to the extension direction of the first extension end 312a.

The first extension end 312a of the first resilient arm 31a and the second extension end 312b of the second resilient arm 31b each have a first limit portion 313a and a second limit portion 313b. In this embodiment, the limit member 3 further comprises a plurality of protection covers 32. The protection covers 32 are disposed on the first limit portions 313a and the second limit portions 313b. The door 10 is coupled to the box 11, the first limit portions 313a and the second limit portions 313b of the limit member 3 hold against the edge of the substrate 2. The first limit portions 313a and the second limit portions 313b are respectively provided with the protection covers 32 to prevent the first limit portions 313a and the second limit portions 313b from directly getting contact with the edge of the substrate 2, and then to prevent the first limit portions 313a and the second limit portions 313b from rubbing from the substrate 2 to bring more contamination particles in the box 11 of the substrate container 1. Furthermore, this prevents the passivation layer of the substrate 2 from being broken to pieces by the first limit portions 313a and the second limit portions 313b to bring more contamination particles in the box 11.

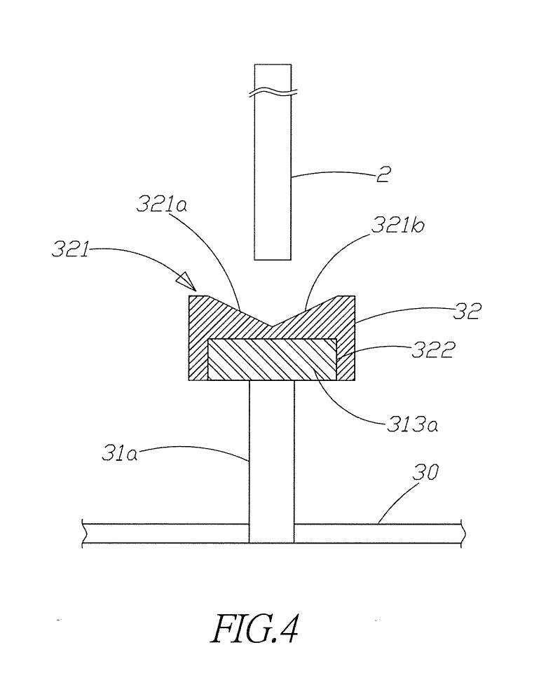

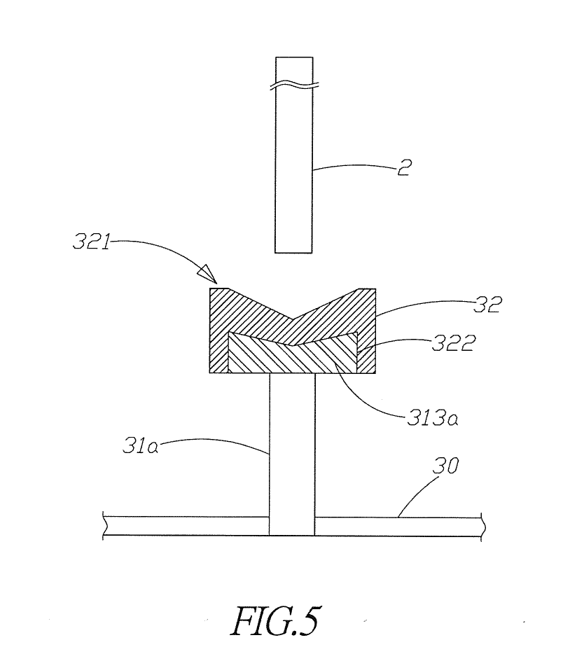

FIG. 4 is a schematic view showing the limit portion and the protection cover according to the first embodiment of the present invention. As shown in the drawing, the first limit portions 313a and the second limit portions 313b of this embodiment have the same configuration, so only the connection configuration of the first limit portion 313a and the protection cover 32 is explained hereinafter. The first limit portion 313a is a protruding block. The protection cover 32 has a contact surface 321 to be contact with the substrate 2 and a recess 322 opposite the contact surface 321. The first limit portion 313a is located in the recess 322 of the protection cover 32, so that the protection cover 32 is disposed on the first limit portion 313a. The first limit portion 313a has a cross-section corresponding in shape to that of the recess 322 of the protection cover 32. For example, the cross-section of the first limit portion 313a is a rectangle, and the cross-section of the recess 322 is also a rectangle. FIG. 5 is a schematic view showing the limit portion and the protection cover according to a second embodiment of the present invention. As shown in the drawing, the cross-section of the first limit portion 313a of this embodiment is an M-like shape, and the cross-section of the recess 322 is also an M-like shape, corresponding to the M-like shape of the cross-section of the first limit portion 313a. The first limit portion 313a mates with the recess 322 of the protection cover 32, preventing disengagement of the protection cover 32 from the first limit portion 313a.

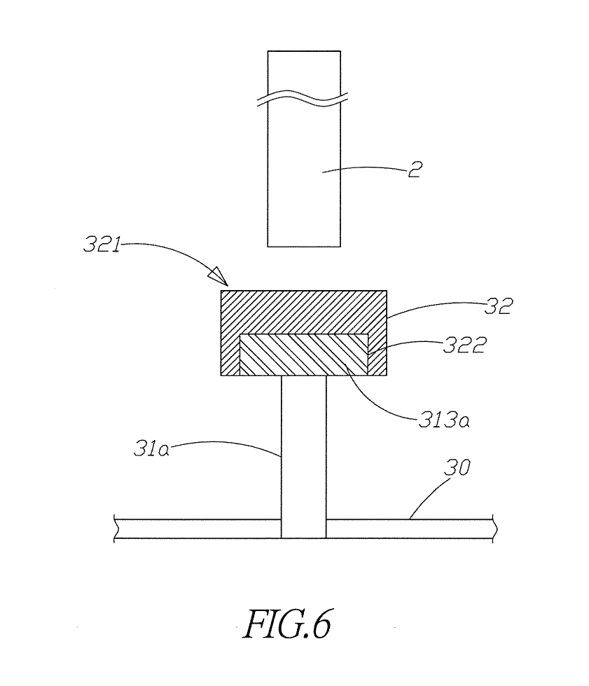

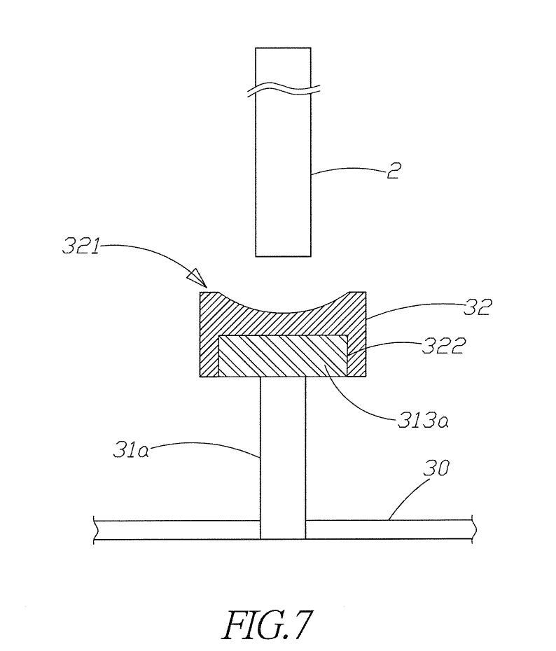

Referring to FIG. 4, the contact surface 321 of the protection cover 32 has a first inclined surface 321a and a second inclined surface 321b. The first inclined surface 321a and the second inclined surface 321b intersect to form a groove and an included angle. The included angle depends on the thickness of the substrate 2. In this embodiment, the substrate 2 is thin, and the included angle of the first inclined surface 321a and the second inclined surface 321b is about 45 degrees. When the substrate 2 is thick, the included angle of the first inclined surface 321a and the second inclined surface 321b will be greater. When the included angle of the first inclined surface 321a and the second inclined surface 321b is 180 degrees, the contact surface 321 of the protection cover 32 is a flat surface, referring to FIG. 6. Besides, the contact surface 321 of the protection cover 32 can be a curved surface, referring to FIG. 7. The radian of the contact surface 321 depends on the thickness of the substrate 2.

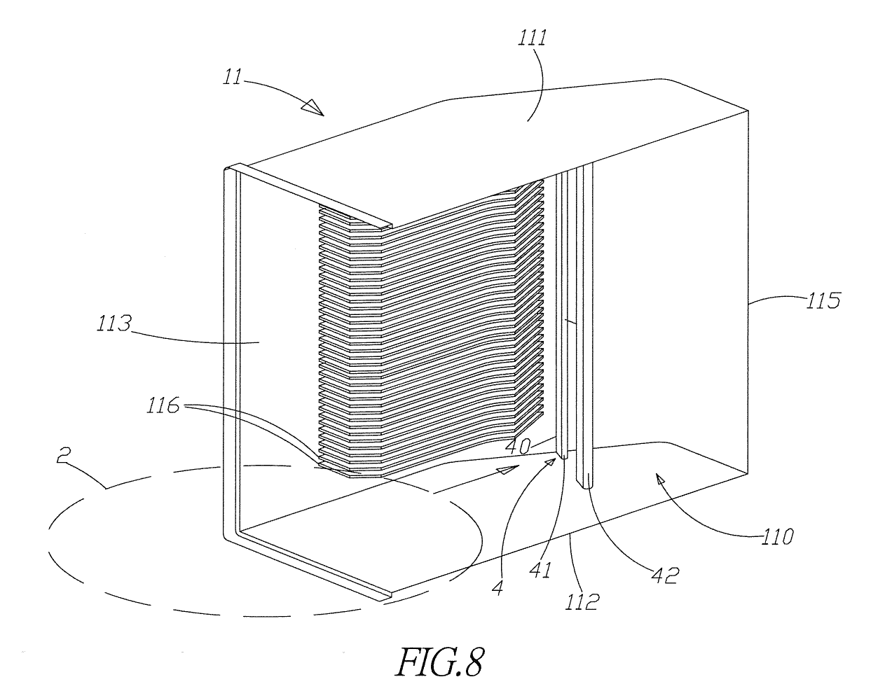

Referring to FIG. 1 and FIG. 8, the box 11 of the substrate container of this embodiment has a top portion 111, a bottom portion 112, a left side wall 113, a right side wall 114, and a rear wall 115. Two sides of the rear wall 115 are respectively connected to the left side wall 113 and the right side wall 114 and located between the top portion 111 and the bottom portion 112. The left side wall 113 and the right side wall 114 are provided with a plurality of support ribs 116. The support ribs 116 are spaced an arranged on the left side wall 113 and the right side wall 114. The support ribs 116 on the left side wall 113 and the support ribs 116 on the right side wall 114 correspond to each other. The substrate 2 is disposed between the support ribs 116. In this embodiment, the box 11 further comprises two limit members 4. The two limit members 4 are respectively disposed on the left side wall 113 and the right side wall 114 and close to the rear wall 115. Each limit member 4 has a strip-like body 40. The strip-like body 40 is perpendicular to the substrate 2 placed in the box 11. The strip-like body 40 has a limit portion 41 at a top end thereof. The limit portion 41 is adapted to hold against the edge of the substrate 2. The limit member 4 of this embodiment further comprises a strip-like protection cover 42. The strip-like protection cover 42 is disposed on the limit portion 41 to prevent the substrate 2 from being contact with the limit portion 41 directly. This can effectively prevent the limit portion 41 to rub against the substrate 2 so as to lower the contamination particles in the substrate container 1 and further prevent the passivation layer of the substrate 2 from being broken to pieces by the limit portion 41 to bring more contamination particles in the box 11.

Accordingly, the limit members of the aforesaid embodiments can have different configurations. But, all have the limit portion used to hold against the edge of the substrate to position the substrate in the substrate container. The limit portion is provided with the protection cover to prevent the substrate from being contact with the limit portion directly to achieve the efficiency of the present invention. In other words, the limit member disposed in the substrate container is provided with the protection cover to touch the substrate so as to achieve the efficiency of the present invention. The limit member can be in various shapes. The position of the limit member in the substrate container is not limited to the aforesaid embodiments.

To sum up, the present invention provides a limit member with a protection cover. The limit member is disposed in a substrate container and has at least one limit portion to hold against the edge of a substrate. The substrate is against the protection cover on the limit portion, not being direct contact with the limit portion. This prevents the substrate from rubbing against the limit member to bring contamination particles, and further prevents the passivation layer of the substrate from being broken to pieces by the limit member to bring more contamination particles.

Although particular embodiments of the present invention have been described in detail for purposes of illustration, various modifications and enhancements may be made without departing from the spirit and scope of the present invention. Accordingly, the present invention is not to be limited except as by the appended claims.

What is claimed is:

1. A limit member, comprising:
a main body disposed in a substrate container and having at least one limit portion; and
at least one protection cover disposed on the limit portion, the protection cover holding against an edge of at least one substrate received in the substrate container.

2. The limit member as claimed in claim 1, wherein the protection cover has a contact surface, and the contact surface is contact with the substrate.

3. The limit member as claimed in claim 2, wherein the contact surface has a first inclined surface and a second inclined surface, the substrate holding against an intersection of the first inclined surface and the second inclined surface, the first inclined surface and the second inclined surface intersecting to form an included angle, the included angle depending on the thickness of the substrate.

4. The limit member as claimed in claim 3, wherein the included angle of the first inclined surface and the second inclined surface is 180 degrees, and the contact surface is a flat surface.

5. The limit member as claimed in claim 2, wherein the contact surface is a curved surface, and the radian of the curved surface depends on the thickness of the substrate.

6. The limit member as claimed in claim 1, wherein the protection cover has a recess, and the limit portion is located in the recess.

7. The limit member as claimed in claim 6, wherein the limit portion has a cross-section corresponding in shape to that of the recess.

8. A limit member, comprising:
a main body mounted to a door of a substrate container;
a plurality of resilient arms, each of the resilient arms having a connection end and an extension end, the connection ends of the resilient arms being connected to two sides of the main body, the extension ends of the resilient arms extending away from the main body, the extension end having a limit portion; and
a plurality of protection covers each disposed on the limit portion of the extension end, the protection covers each holding against an edge of at least one substrate received in the substrate container.

9. The limit member as claimed in claim 8, wherein each of the protection covers has a contact surface, and the contact surface is contact with the substrate.

10. The limit member as claimed in claim 9, wherein the contact surface has a first inclined surface and a second inclined surface, the substrate holding against an intersection of the first inclined surface and the second inclined surface, the first inclined surface and the second inclined surface intersecting to form an included angle, the included angle depending on the thickness of the substrate.

11. The limit member as claimed in claim 10, wherein the included angle of the first inclined surface and the second inclined surface is 180 degrees, and the contact surface is a flat surface.

12. The limit member as claimed in claim 9, wherein the contact surface is a curved surface, and the radian of the curved surface depends on the thickness of the substrate.

13. The limit member as claimed in claim 8, wherein each of the protection covers has a recess, and the limit portion is located in the recess.

14. The limit member as claimed in claim 13, wherein the limit portion has a cross-section corresponding in shape to that of the recess.

15. A limit member, comprising:
at least one main body disposed on a side wall of a box of a substrate container and having at least one limit portion, the main body being perpendicular to at least one substrate received in the substrate container; and
at least one protection cover disposed on the limit portion, the protection cover holding against an edge of the substrate.

16. The limit member as claimed in claim 15, wherein the protection cover has a contact surface, and the contact surface is contact with the substrate.

17. The limit member as claimed in claim 15, wherein the protection cover has a recess, and the limit portion is located in the recess.
